(19) United States
(12) Patent Application Publication
(10) Pub. No.: US 2026/0114290 A1
(43) Pub. Date: Apr. 23, 2026

(54) APPARATUSES AND METHODS FOR FACILITATING AN ADVANCED HIGH SPEED INTERCONNECT STRUCTURE FORMED BY AN INTEGRATED CIRCUIT, BUMP BALLS, AND PACKAGING

(71) Applicant: CIENA CORPORATION, Hanover, MD (US)

(72) Inventors: Kaisheng Hu, Kanata (CA); Douglas Stuart McPherson, Ottawa (CA); William Che Knisely, Ottawa (CA); Aravinthan Vigneswaran, Kanata (CA)

(73) Assignee: CIENA CORPORATION, Hanover, MD (US)

(21) Appl. No.: 18/921,115

(22) Filed: Oct. 21, 2024

(51) Int. Cl. H01L 23/66; H01L 23/00; H01L 23/552

(52) U.S. Cl. CPC H10W 44/20; H10W 42/20; H10W 44/216; H10W 72/248; H10W 72/952; H10W 90/724

(57) ABSTRACT

Embodiments of the subject disclosure are directed to, for example, a circuit or device that includes a package corresponding to a first waveguide, a die corresponding to a second waveguide, and an array of bump balls disposed between the package and the die. Various embodiments may include a circuit or device that includes a plurality of ground planes, a plurality of ground bump balls, and a plurality of package ground planes, where the plurality of ground planes, the plurality of ground bump balls, and the plurality of package ground planes form a Faraday cage. Other embodiments are disclosed.

### FIELD OF THE DISCLOSURE

The subject disclosure relates to apparatuses and methods for facilitating an advanced high speed interconnect structure formed by an integrated circuit, bump balls, and packaging.

### BACKGROUND

With advancements in integrated circuit (IC) technologies, IC manufacturers and fabricators have been able to accommodate increased functionality, at increased speeds/frequencies, on a given unit/size die/chip. For example, in the near-term the operational speed of digital to analog converter (DAC) and analog to digital converter (ADC) ICs is poised to reach the 100 GHz operating frequency range. In these and other scenarios involving high-speed signaling, an interconnection between an IC die and an IC package has emerged as a bottleneck or performance limitation. According to microwave theory, high-order non-transverse electromagnetic (non-TEM) modes are susceptible to excitation, leading to resonance and significant notches in the signal transfer function. Parasitic parameters originating from bump pads, bump balls and metal ground planes further degrade IC performance. Consequently, despite reasonable measures having been taken to facilitate circuit design for, e.g., DAC and ADC ICs, the operational frequency of the ICs is lowered/limited based on the interface of the IC die and the IC package.

### BRIEF DESCRIPTION OF THE DRAWINGS

Reference will now be made to the accompanying drawings, which are not necessarily drawn to scale, and wherein:

FIG. 1 is a block diagram illustrating an exemplary, non-limiting embodiment of a circuit featuring a transition structure in accordance with various aspects described herein.

FIG. 2 depicts a cross-section of a cavity structure formed by a die, a plurality of bump balls, and a package in accordance with aspects of this disclosure.

FIGS. 3A and 3B illustrate a map pattern for bump balls and layout in accordance with aspects of this disclosure.

FIGS. 4A and 4B illustrate various package layers in accordance with aspects of this disclosure.

FIGS. 5A and 5B illustrate various die layers in accordance with aspects of this disclosure

FIG. 6 illustrates various layers of a die in accordance with aspects of this disclosure.

### DETAILED DESCRIPTION

The subject disclosure describes, among other things, illustrative embodiments for enhancing signal characteristics associated with a circuit (e.g., an integrated circuit), such as for example in relation to high-speed/high-frequency signaling. Other embodiments are described in the subject disclosure.

One or more aspects of the subject disclosure include, in whole or in part, a package corresponding to a first waveguide; a die corresponding to a second waveguide; and an array of bump balls disposed between the package and the die.

One or more aspects of the subject disclosure include, in whole or in part, a plurality of ground planes; a plurality of ground bump balls; and a plurality of package ground planes, wherein the plurality of ground planes, the plurality of ground bump balls, and the plurality of package ground planes form a Faraday cage.

One or more aspects of the subject disclosure include, in whole or in part, a package including a first layer; a differential coplanar waveguide with ground (CPWG) on the first layer; an array of bump balls located adjacent to the package; and a die located adjacent to the array of bump balls.

By way of introduction, aspects of this disclosure provide/facilitate a chip-to-package transition for a circuit (e.g., an integrated circuit) with broadband performance reaching at least as high as 200 GHz. Utilization of the techniques of this disclosure may enhance signal quality characteristics (e.g., a realization of a reduction in crosstalk, insertion loss, return loss, etc.) as it relates to a deployment of a circuit or chip design.

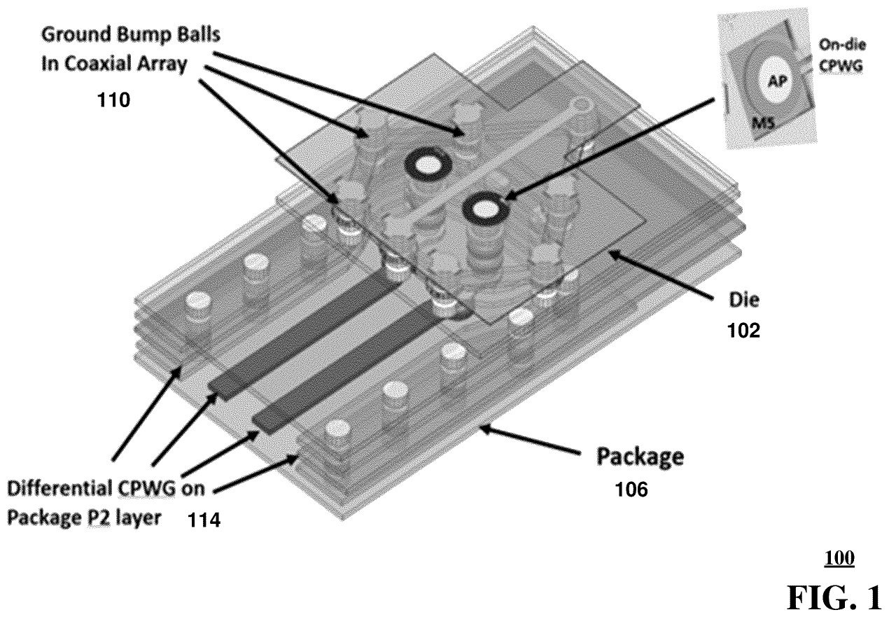

Referring now to FIG. 1, a diagram/outline drawing of a circuit 100 (e.g., an IC) is shown that provides for an interface between a die 102 and a package 106 in accordance with aspects of this disclosure. In particular, in FIG. 1 a transition structure for supporting such an interface is shown. High-speed signals may pass through bump balls/pads on one or more layers (e.g., the aluminum for bond pad (AP) layer) of the die 102, then descend to the bump balls with, e.g., six to eight ground bump balls 110 surrounding every two signal bumps/bump balls. These bumps may connect with the package bump pad on, e.g., the package's metal 1 (M1) layer. The bumps may include controlled-collapse chip connection (C4) bumps and/or copper pillar bumps (CPB), for example. Subsequently, the high-speed signal may descend to, e.g., a P2 layer through stackup vias, before finally exiting through a differential coplanar waveguide with ground (CPWG) 114 on the P2 layer. High-density stitching ground vias may be located on the ground planes beside the CPWG's signal conductors on the same layer, to reduce radiation losses and crosstalk, thereby enhancing signal integrity.

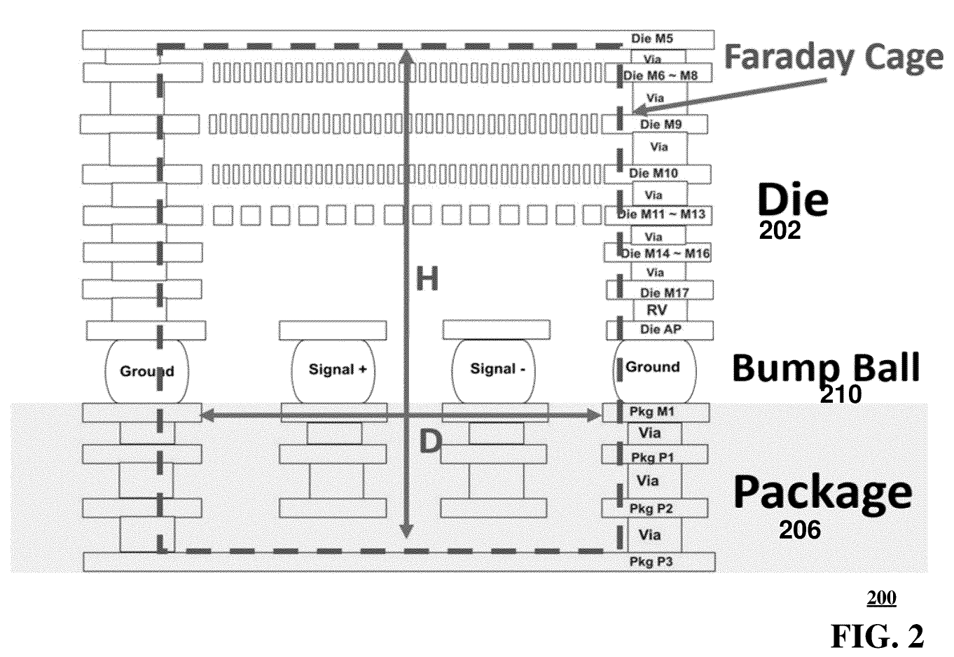

With reference now to FIG. 2, a cross-sectional diagram of a cavity structure 200 (relative to a height (H) and width or diameter (D) superimposed in FIG. 2) formed by an IC die 202, package 206, and bump balls/bump ball array 210 in accordance with aspects of this disclosure is shown. As shown, the configuration in FIG. 2 may be used to form a “faraday cage” of ground (through the connection of the ground bump balls of the bump balls 210, to the die components of the die 202, and to the package components of the package 206), which may be useful from a perspective of blocking or reducing an emission of radio frequency (RF) energy/radiation, which in turn may enhance crosstalk performance by preventing or reducing signal interference.

The height (H) and the diameter (D) in FIG. 2 may be designed/selected to prevent an excitation of resonance modes below a potential operating range of interest (e.g., below 200 GHz), in accordance with Equation (1) shown below:

$${f}_{r} = \frac{{c}_{0}}{2 π} \cdot \sqrt{\frac{{m}^{2}}{{D}^{2}} + \frac{{n}^{2}}{{H}^{2}}} / \sqrt{{ε}_{r}} \qquad Equation ( 1 )$$

where: fᵣ is the first resonant frequency (in Hz), c₀ is the speed of light in a vacuum (e.g., 3×10⁸ m/s), m and n are mode indices (e.g., for a first resonant mode, m=0 and n=1), H is the height and D is the diameter of the cage, and εᵣ is the relative permittivity (dielectric constant) of the materials inside the cage.

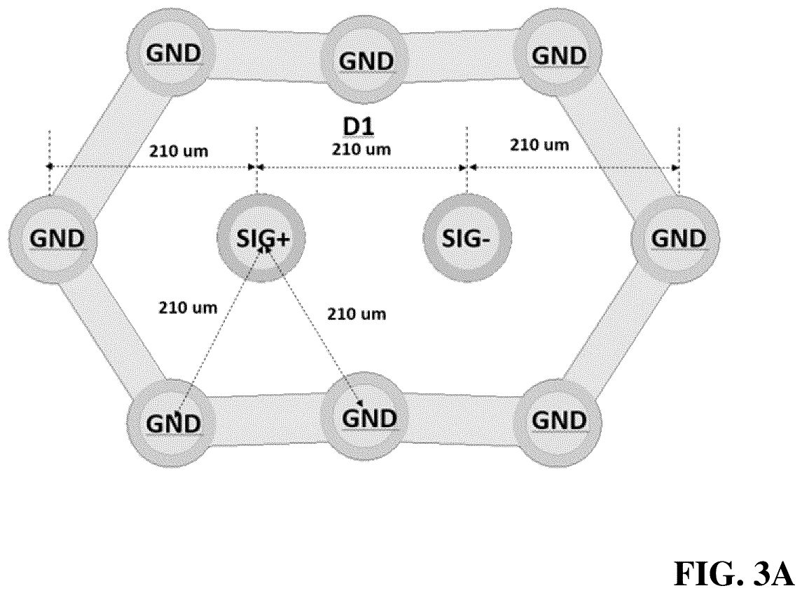

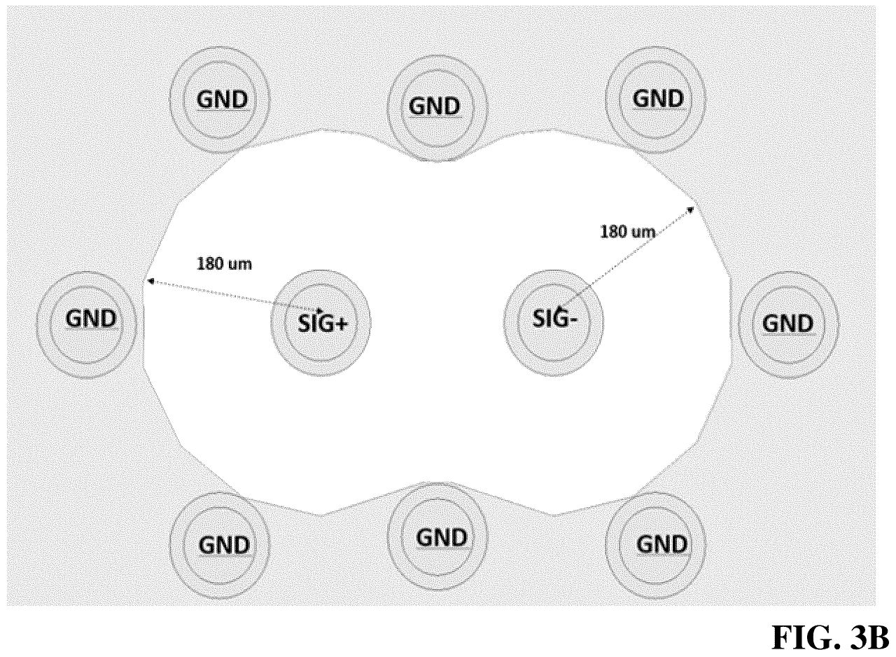

In some embodiments, it may be desirable to obtain a differential impedance of a given value (e.g., 100 ohms), or range of values (e.g., 100 ohms+/−10%), via a collective cavity structure that includes the (metal) layers of both the IC/die and package, in conjunction with the bump balls. This differential impedance (Z_{diff}) may be expressed as shown in Equation (2) below:

$${Z}_{diff} = \frac{138}{\sqrt{{D}_{k}}} \cdot ln ( \frac{{D}_{1} + {R}_{2}}{{D}_{1} - {R}_{2}} ) \qquad Equation ( 2 )$$

Where Z_{diff} is the differential impedance in ohms (Ω), Dₖ is the dielectric constant of substrate materials that are used, D₁ is the center-to-center distance between two bump balls for a signal (see FIG. 3A for an example of parameter D₁) and R₂ is the radius of a bump ball.

FIG. 3A and FIG. 3B illustrate a pattern of bump balls and layout on package layers M1 and P1, respectively, relative to/for signal (SIG) and ground (GND). Any values/distances shown in FIGS. 3A-3B are illustrative as part of one or more exemplary embodiments, which is to say that different values may be used in a given embodiment.

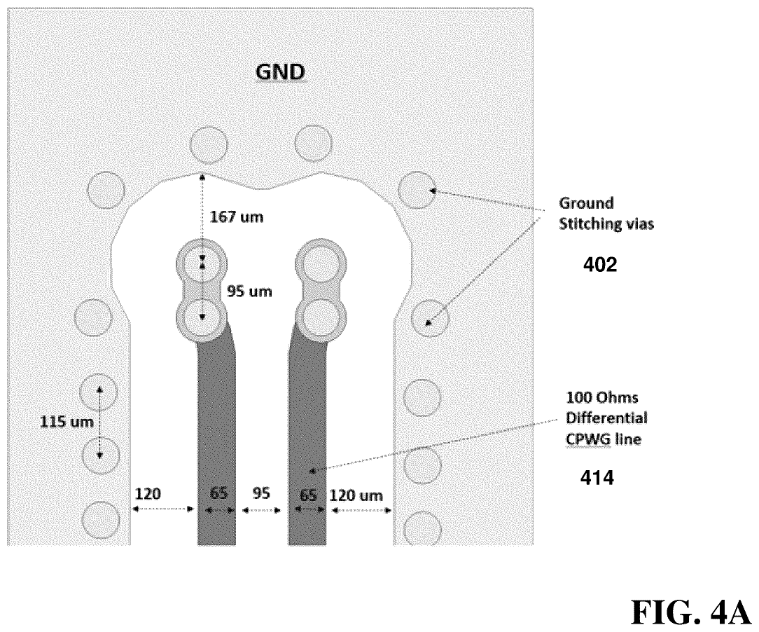

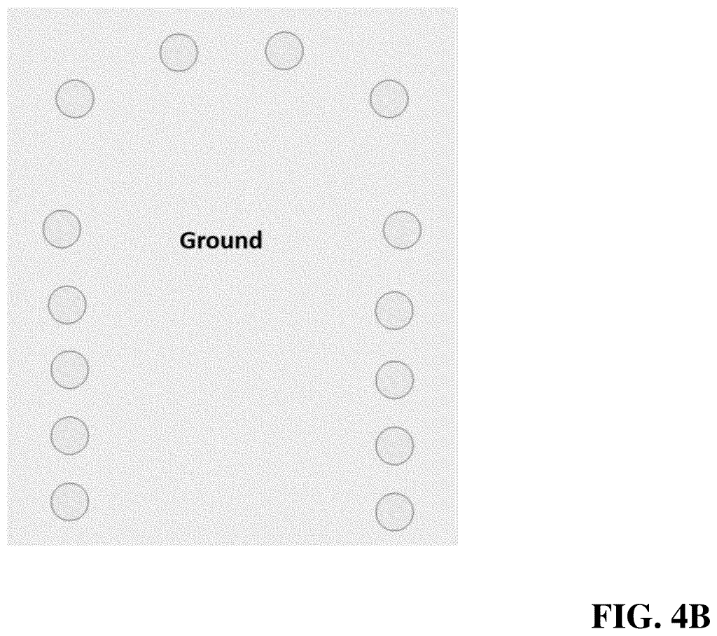

FIG. 4A and FIG. 4B illustrate a layout on package layers P2 and P3, respectively, inclusive of ground stitched vias 402 and differential CPWG line 414. Again, any values or distances shown in FIGS. 4A-4B are illustrative as part of one or more exemplary embodiments, which is to say that different values may be used in a given embodiment.

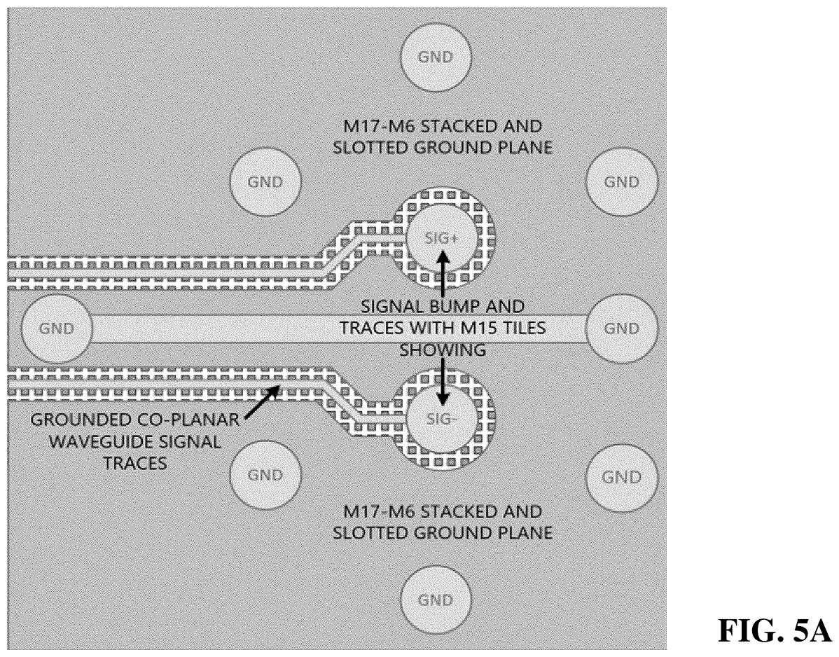

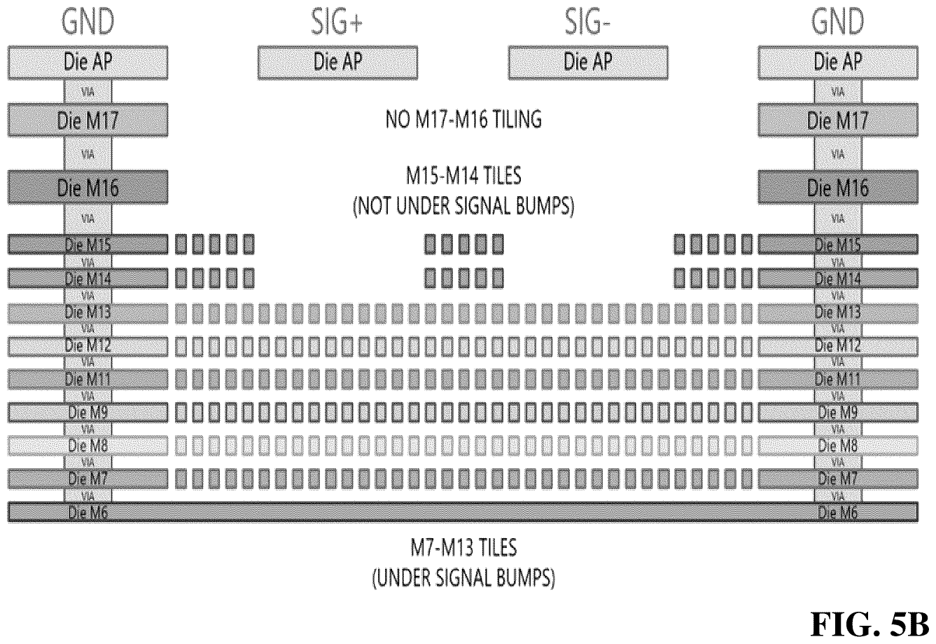

FIG. 5A illustrates a top-view layout on a die for an IC (e.g., a DAC IC) on an AP layer in accordance with aspects of this disclosure. The layout of FIG. 5A is shown relative to signal (SIG), ground (GND), and CPWG signal traces. FIG. 5B demonstrates the same layout as FIG. 5A, except in/from a cross-sectional view/perspective. It is noted that the particular arrangement shown in FIG. 5B (in terms of, e.g., tiles or tiling) is illustrative, which is to say that other arrangements may be used without departing from the scope and spirit of this disclosure.

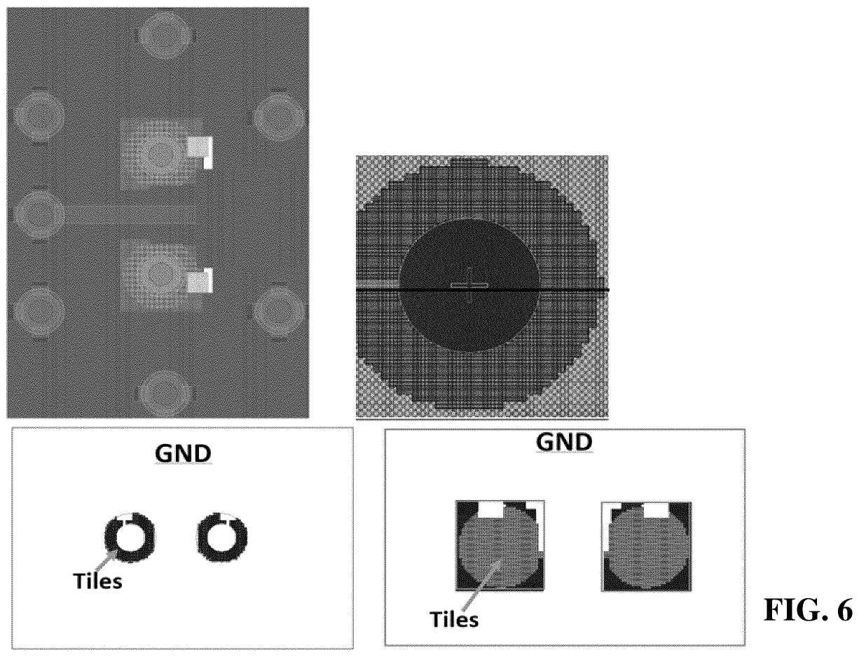

FIG. 6 illustrates a layout on a die (e.g., an ADC die) for an AP layer and M6-M17 layers. With reference to FIGS. 5A, 5B and 6, directly under a bump/bump ball as shown, there may be an M6 ground plane, M7-M13 tiles (only), and no tiles on M14-M17. Of course, a different arrangement may be utilized in a given embodiment.

Various embodiments incorporating one or more aspects/features of this disclosure may provide a chip-to-package transition with acceptable broadband performance up to at least 200 GHz via an easy and low-cost implementation process. As set forth herein, a three-level transfer structure of waveguide (package)-coaxial (bump ball)-waveguide (die), as shown in FIGS. 1 and 2 may be utilized to realize such a performance. A Faraday cage of ground, formed by IC ground planes, ground bump balls, and package ground planes may be realized/obtained, which may help to reduce RF radiation emissions (in terms of ingress or egress relative to the IC in question). As such, aspects of signal integrity may be enhanced (e.g., crosstalk or signal interference may be reduced). Aspects of this disclosure, inclusive of aspects of a wide-bandwidth transition structure, may include: a coaxial ring of bump balls and ground planes (see, e.g., FIGS. 3A-3B), a differential CPWG line with high-density stitching ground vias on package (see, e.g., FIGS. 4A-4B), and/or an on-die CPWG trace at an AP layer (see, e.g., FIGS. 5A, 5B, and 6).

In accordance with aspects of this disclosure, RF resonance modes may be excluded from a useful operating frequency band of interest (e.g., sub 200 GHz) by: tuning a faraday cage of ground formed by IC ground planes, ground bump balls, and package ground planes, reducing parasitic parameters through tuning of a coaxial ring of bump balls and ground planes, and/or decreasing impedance discontinuities by adjusting line (e.g., CPWG line) and via shapes/dimensions.

What has been described above includes mere examples of various embodiments. It is, of course, not possible to describe every conceivable combination of components or methodologies for purposes of describing these examples, but one of ordinary skill in the art can recognize that many further combinations and permutations of the present embodiments are possible. Accordingly, the embodiments disclosed and/or claimed herein are intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

Computing devices and circuits typically comprise a variety of media, which can comprise computer-readable storage media and/or communications media, which two terms are used herein differently from one another as follows. Computer-readable storage media can be any available storage media that can be accessed by the computer and comprises both volatile and nonvolatile media, removable and non-removable media. By way of example, and not limitation, computer-readable storage media can be implemented in connection with any method or technology for storage of information such as computer-readable instructions, program modules, structured data or unstructured data. Computer-readable storage media can comprise the widest variety of storage media including tangible and/or non-transitory media which can be used to store desired information. In this regard, the terms “tangible” or “non-transitory” herein as applied to storage, memory or computer-readable media, are to be understood to exclude only propagating transitory signals per se as modifiers and do not relinquish rights to all standard storage, memory or computer-readable media that are not only propagating transitory signals per se.

As may also be used herein, the term(s) “operably coupled to”, “coupled to”, and/or “coupling” includes direct coupling between items and/or indirect coupling between items via one or more intervening items. Such items and intervening items include, but are not limited to, junctions, communication paths, components, circuit elements, circuits, functional blocks, and/or devices. As an example of indirect coupling, a signal conveyed from a first item to a second item may be modified by one or more intervening items by modifying the form, nature or format of information in a signal, while one or more elements of the information in the signal are nevertheless conveyed in a manner than can be recognized by the second item. In a further example of indirect coupling, an action in a first item can cause a reaction on the second item, as a result of actions and/or reactions in one or more intervening items.

Although specific embodiments have been illustrated and described herein, it should be appreciated that any arrangement which achieves the same or similar purpose may be substituted for the embodiments described or shown by the subject disclosure. The subject disclosure is intended to cover any and all adaptations or variations of various embodiments. Combinations of the above embodiments, and other embodiments not specifically described herein, can be used in the subject disclosure. For instance, one or more features from one or more embodiments can be combined with one or more features of one or more other embodiments. In one or more embodiments, features that are positively recited can also be negatively recited and excluded from the embodiment with or without replacement by another structural and/or functional feature. The steps or functions described with respect to the embodiments of the subject disclosure can be performed in any order. The steps or functions described with respect to the embodiments of the subject disclosure can be performed alone or in combination with other steps or functions of the subject disclosure, as well as from other embodiments or from other steps that have not been described in the subject disclosure. Further, more than or less than all of the features described with respect to an embodiment can also be utilized.

What is claimed is:

1. A circuit, comprising:
a package corresponding to a first waveguide;
a die corresponding to a second waveguide; and
an array of bump balls disposed between the package and the die, the array of bump balls comprising at least one signal bump ball connecting the first waveguide to the second waveguide and a coaxial ring of ground bump balls.

2. The circuit of claim 1, further comprising:
a Faraday cage of ground formed by die ground planes, the ground bump balls, and package ground planes.

3. The circuit of claim 1, wherein the at least one signal bump ball includes two signal bump balls to carry a differential signal, and the coaxial ring of ground bump balls surrounds the two signal bump balls.

4. The circuit of claim 3, wherein the coaxial ring of ground bump balls is disposed relative to a ground plane.

5. The circuit of claim 1, wherein the first waveguide comprises a differential coplanar waveguide with ground (CPWG) line.

6. The circuit of claim 5, wherein the differential CPWG line has an impedance of 100 ohms+/−10%.

7. The circuit of claim 5, further comprising:
ground vias located on ground planes beside signal conductors of the differential CPWG line.

8. The circuit of claim 1, wherein the second waveguide comprises a coplanar waveguide with ground (CPWG) trace located on the die.

9. The circuit of claim 8, wherein the CPWG trace is on an aluminum for bond pad (AP) layer of the die.

10. A device comprising:
a plurality of ground planes;
a plurality of ground bump balls; and
a plurality of package ground planes,
wherein the plurality of ground planes, the plurality of ground bump balls, and the plurality of package ground planes form a Faraday cage.

11. The device of claim 10, wherein a height and a diameter of the Faraday cage prevent an excitation of resonance modes below 200 GHz operation of the device.

12. The device of claim 10, further comprising:
a differential coplanar waveguide with ground (CPWG) line.

13. The device of claim 12, wherein the differential CPWG line has an impedance of 100 ohms+/−10%.

14. The device of claim 12, further comprising:
ground vias located on ground planes beside signal conductors of the differential CPWG line.

15. The device of claim 10, further comprising:
a die; and
a coplanar waveguide with ground (CPWG) trace located on the die.

16. The device of claim 15, wherein the CPWG trace is on an aluminum for bond pad (AP) layer of the die.

17. A circuit comprising:
a package including a first layer;
a differential coplanar waveguide with ground (CPWG) on the first layer;
an array of bump balls located adjacent to the package; and
a die located adjacent to the array of bump balls.

18. The circuit of claim 17, wherein the array of bump balls includes a plurality of ground bump balls and a plurality of signal bump balls.

19. The circuit of claim 18, wherein the plurality of ground bump balls, a first plurality of ground planes associated with the die, and a second plurality of ground planes associated with the package form a Faraday cage.

20. The circuit of claim 17, wherein the circuit includes a digital to analog converter, an analog to digital converter, or a combination thereof.
